(19) United States
(12) Patent Application Publication
(10) Pub. No.: US 2025/0081740 A1
(43) Pub. Date: Mar. 6, 2025

(54) DISPLAY SUBSTRATE AND MANUFACTURING METHOD THEREOF, AND DISPLAY DEVICE

(71) Applicant: BOE TECHNOLOGY GROUP CO., LTD., Beijing (CN)

(72) Inventors: Wei QUAN, Beijing (CN); Juanjuan YOU, Beijing (CN); Bin BO, Beijing (CN); Cheng XU, Beijing (CN)

(21) Appl. No.: 18/555,905

(22) PCT Filed: Feb. 27, 2023
(86) PCT No.: PCT/CN2023/078509

§ 371 Date: Oct. 18, 2023

(51) Int. Cl. H10K 59/122; H10K 59/12; H10K 59/173

(52) U.S. Cl. CPC H10K 59/122; H10K 59/1201; H10K 59/173

(57) ABSTRACT

A display substrate is provided and includes a base substrate; a plurality of sub-pixels, a pixel-defining pattern, and a first filling structure. The sub-pixels are on the base substrate, each of at least part of the plurality of sub-pixels includes a light-emitting element, the pixel-defining pattern includes a plurality of openings and a defining portion that surrounds the plurality of openings, the defining portion includes at least one cavity surrounding at least one opening, and the first filling structure is in the cavity, and a surface, away from the base substrate, of the first filling structure is farther away from the base substrate than a surface, away from the base substrate, of at least a portion of the light-emitting functional layer in the opening.

### TECHNICAL FIELD

At least one embodiment of the present disclosure relates to a display substrate and a manufacturing method thereof, and a display device.

### BACKGROUND

Organic Light-Emitting Diode (OLED) is an organic electroluminescent device, which has advantages of self-light emitting, wide angle of view, high contrast ratio, etc., and therefore it is widely used in smart products such as a mobile phone, a TV, and a notebook computer, a display technology using the organic light-emitting diode has become an important display technology.

### SUMMARY

At least one embodiment of the disclosure provides a display substrate and a manufacturing method thereof, and a display device.

At least one embodiment of the disclosure provides a display substrate, comprising: a base substrate: a plurality of sub-pixels on the base substrate, wherein each of at least part of the plurality of sub-pixels comprises a light-emitting element, the light-emitting element comprises a light-emitting functional layer, a first electrode and a second electrode on both sides of the light-emitting functional layer in a first direction, the first electrode is between the light-emitting functional layer and the base substrate, and the first direction is perpendicular to the base substrate: a pixel-defining pattern, the pixel-defining pattern comprising a plurality of openings and a defining portion that surrounds the plurality of openings, at least a portion of the light-emitting element in the opening, wherein the defining portion comprises at least one cavity, and the cavity surrounds at least one opening, and the display substrate further comprises a first filling structure, and the first filling structure is in the cavity, and a surface, away from the base substrate, of the first filling structure is farther away from the base substrate than a surface, away from the base substrate, of at least a portion of the light-emitting functional layer in the opening.

For example, in the display substrate provided by at least one embodiment of the disclosure, a minimum distance in a second direction between an edge of a surface of the defining portion at a side away from the base substrate and an edge of an orthographic projection of the first filling structure on the base substrate, which are adjacent to each other, is a first distance, and the second direction is a direction perpendicular to an extending direction of the edges: a distance between a center line of an orthographic projection of the defining portion on the display substrate and an orthographic projection of a first filling structure next to the center line on the display substrate is a second distance, the first distance is smaller than the second distance, and the center line is parallel to an extending direction of the defining portion.

For example, in the display substrate provided by at least one embodiment of the disclosure, two cavities are arranged between two adjacent sub-pixels that are arranged in the second direction, and orthographic projections of the two cavities on the base substrate are on two side of the center line, respectively.

For example, in the display substrate provided by at least one embodiment of the disclosure, the defining portion further comprises a plurality of grooves, at least one of the plurality of grooves surrounds the opening, and the groove is on a side of the cavity away from the substrate, the display substrate further comprises a second filling structure, the second filling structure is in the groove, a material of the second filling structure is different from a material of the defining portion, and the second filling structure comprises a light-transmitting material, wherein the plurality of grooves comprise a first groove portion and a second groove portion, and the defining portion comprises a first defining portion and a second defining portion, and in a second direction, the first defining portion, the second filling structure in the first groove portion, the second defining portion, and the second filling structure in the second groove portion are arranged in sequence to form a light filtering structure, and the second direction is perpendicular to an extending direction of the defining portion, the first defining portion is farther away from a center line of an orthographic projection of the defining portion on the base substrate than the second defining portion, and the first groove portion is farther from the center line than the second groove portion.

For example, in the display substrate provided by at least one embodiment of the disclosure, an orthographic projection of the first groove portion on the base substrate and an orthographic projection of the second groove portion on the base substrate overlap with an orthographic projection of a same cavity on the base substrate.

For example, in the display substrate provided by at least one embodiment of the disclosure, a surface of the second filling structure away from the base substrate is flush with at least a portion of a surface of the defining portion away from the base substrate.

For example, in the display substrate provided by at least one embodiment of the disclosure, a surface of the second filling structure close to the base substrate is flush with at least a portion of the surface of the first filling structure away from the base substrate.

For example, in the display substrate provided by at least one embodiment of the disclosure, in the second direction, a size of the second filling structure is smaller than a size of the first filling structure.

For example, in the display substrate provided by at least one embodiment of the disclosure, the first defining portion, the second filling structure in the first groove portion, the second defining portion, and the second filling structure in the second groove portion in the light filtering structure each satisfy: d=λ/(4*n), wherein, d represents a thickness of any one of the first defining portion, the second filling structure in the first groove portion, the second defining portion, and the second filling structure in the second groove portion in the second direction, λ represents a wavelength of incident light, n represents a refractive index of any one of the first defining portion, the second filling structure in the first groove portion, the second defining portion, and the second filling structure in the second groove portion.

For example, in the display substrate provided by at least one embodiment of the disclosure, in the light filtering structure, a thickness d1 of the first defining portion in the second direction is greater than a thickness d3 of the second filling structure in the first groove portion in the second direction.

For example, in the display substrate provided by at least one embodiment of the disclosure, in the light filtering structure, a refractive index n1 of the first defining portion and a refractive index n2 of the second defining portion respectively satisfy: 1.43≤n1≤1.47, and 1.43≤n2≤1.47.

For example, in the display substrate provided by at least one embodiment of the disclosure, in the light filtering structure, a thickness d1 of the first defining portion and a thickness d2 of the second defining portion respectively satisfy: 75 nm≤d1≤130 nm, 75 nm≤d2≤130 nm.

For example, in the display substrate provided by at least one embodiment of the disclosure, in the light filtering structure, a refractive index n3 of the second filling structure in the first groove portion and a refractive index n4 of the second filling structure in the second groove portion respectively satisfy: 1.83≤n3≤1.87, 1.83≤n4≤1.87.

For example, in the display substrate provided by at least one embodiment of the disclosure, in the light filtering structure, a thickness d3 of the second filling structure in the first groove portion and a thickness d4 of the second filling structure in the second groove portion respectively satisfy: 60 nm≤d1≤100 nm, 60 nm≤d2≤100 nm.

For example, in the display substrate provided by at least one embodiment of the disclosure, a size of the first filling structure in the first direction is not greater than ½ of a maximum size of the defining portion in the first direction.

For example, in the display substrate provided by at least one embodiment of the disclosure, in the second direction, a size of the first filling structure is 1/10 to ⅙ of a maximum size of the defining portion.

For example, in the display substrate provided by at least one embodiment of the disclosure, a surface of the first filling structure close to the base substrate is flush with a bottom surface of the defining portion close to the base substrate.

For example, in the display substrate provided by at least one embodiment of the disclosure, an orthographic projection of the first filling structure on the base substrate does not overlap with an orthographic projection of the first electrode on the base substrate.

For example, in the display substrate provided by at least one embodiment of the disclosure, a material of the first filling structure is a light-shielding material.

For example, in the display substrate provided by at least one embodiment of the disclosure, a thermal conductivity K of the material of the first filling structure satisfies: 350<K<550.

For example, in the display substrate provided by at least one embodiment of the disclosure, a material of the first filling structure comprises silver.

For example, in the display substrate provided by at least one embodiment of the disclosure, at least two light filtering structures are arranged between two adjacent sub-pixels arranged in the second direction.

For example, in the display substrate provided by at least one embodiment of the disclosure, the material of the second filling structure comprises silicon nitride.

At least one embodiment of the disclosure provides a display device, comprising the display substrate according to any embodiments as mentioned above.

At least one embodiment provides a manufacturing method of a display substrate, comprising: forming a first electrode, a light-emitting functional layer, and a second electrode of a light-emitting element on the base substrate: before forming the light-emitting functional layer, forming a pixel-defining pattern on the first electrode, wherein the pixel-defining pattern comprises a plurality of openings and a defining portion that surrounds the plurality of openings, each of the plurality of openings exposes at least a portion of the first electrode: forming a first type of groove in the defining portion, the first type of groove surrounding at least one of the plurality of openings; and forming a first filling structure in the first type of groove, wherein a surface, away from the base substrate, of the first filling structure is farther away from the base substrate than a surface, away from the base substrate, of at least a portion of the light-emitting functional layer in the opening.

For example, in the manufacturing method of the display substrate provided by at least one embodiment of the disclosure, after forming the first filling structure, the manufacturing method further comprises: filling a portion of the first type of groove other than a space filled with the first filling structure with a material of the defining portion: forming a plurality of second type of grooves in the defining portion on a side of the first filling structure away from the base substrate, wherein at least one second type of groove surrounds the opening, the plurality of second type of grooves comprises a first groove portion and a second groove portion, and the defining portion comprises a first defining portion and a second defining portion: forming second filling structures in the second type of grooves, wherein a material of the second filling structures is different from the material of the defining portion, and the second filling structures comprise a light-transmitting material: the first defining portion, the second filling structure in the first groove portion, the second defining portion, and the second filling structure in the second groove portion are arranged in sequence to form a light filtering structure.

### BRIEF DESCRIPTION OF DRAWINGS

In order to clearly illustrate the technical solution of the embodiments of the disclosure, the drawings of the embodiments will be briefly described in the following: it is obvious that the described drawings are only related to some embodiments of the disclosure and thus are not limitative of the disclosure.

FIG. 1 is a schematic diagram of a partial planar structure of a display substrate provided by an embodiment of the present disclosure.

FIG. 2 is a schematic diagram of a partial cross-sectional structure taken in a section line AA′ illustrated in FIG. 1.

FIG. 3 is an enlarged schematic diagram of the partial cross-sectional structure illustrated in FIG. 2.

FIG. 4 is a spectral schematic diagram after light-emitting brightness of a light-emitting element in a display substrate illustrated by an embodiment of the present disclosure is enhanced.

FIG. 5 is another spectral schematic diagram after light-emitting brightness of a light-emitting element in a display substrate provided by an embodiment of the present disclosure is enhanced.

FIG. 6 is a schematic diagram of a partial planar structure of another display substrate provided by an embodiment of the present disclosure.

FIG. 7 is a schematic diagram of a partial cross-sectional structure of a display device provided by at least one embodiment of the present disclosure.

FIG. 8 to FIG. 13 diagrams showing processes of a manufacturing method of a display substrate illustrated in at least one embodiment of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

Unless otherwise specified, the technical terms or scientific terms used in the disclosure shall have normal meanings understood by those skilled in the art. The words “first”, “second” and the like used in the disclosure do not indicate the sequence, the number or the importance but are only used for distinguishing different components. The word “comprise”, “include” or the like only indicates that an element or a component before the word contains elements or components listed after the word and equivalents thereof, not excluding other elements or components.

As used in embodiments of the present disclosure, the features “perpendicular”, “parallel”, and “identical” include the features “perpendicular”, “parallel”, and “identical,” etc. in the strict sense, as well as “approximately perpendicular”, “approximately parallel”, and “approximately identical,” etc., which include a certain amount of error, are indicated to be within a range of acceptable deviations for a particular value as determined by a person of ordinary skill in the art, taking into account the measurement and the error associated with the measurement of the particular quantity (e.g., the limitation of the measurement system). The “center” in the embodiments of the present disclosure may include a strictly geometric center position and a roughly central position in a small area around the geometric center.

Generally, an organic light-emitting diode uses an organic semiconductor material and a light-emitting material to emit light through a charge carrier injecting and recombination driven by an electric field. A principle of the organic light-emitting diode is to use a transparent electrode and a metal electrode as an anode and a cathode of the device, respectively, driven by a certain voltage, electrons and holes are injected from the cathode and the anode into an electron transport layer and a hole transport layer, respectively, and the electrons and the holes are respectively migrated to a light-emitting functional layer through the electron transport layer and the hole transport layer, and meet in the light-emitting functional layer to form an exciton so that a light-emitting molecule is excited, which emits visible light through radiation relaxation. For example, the transparent electrode includes indium tin oxide (ITO). For example, different light-emitting elements may have light-emitting functional layers of different materials, so as to emit light of different colors. The organic light-emitting diode is a self-light emitting device, which has advantages such as low weight, small thickness and good bending resistance.

For example, organic light-emitting diodes can be divided into passive matrix driving organic light-emitting diode (PMOLED) and active matrix driving organic light-emitting diode (AMOLED) according to driving methods. The active matrix driving organic light-emitting diode has advantages such as low manufacturing cost, low power consumption, being adaptable to direct current driving for a portable device, and wide operating temperature range.

For example, for a large-sized AMOLED display device, the backplane power line has a certain resistance. During an OLED device emitting light, the driving current for all sub-pixels is provided to each sub-pixel by a scanning driving unit through a driving control line. Therefore, in a light-emitting phase, the voltage input to a sub-pixel near the scanning driving unit is higher than the voltage input to a sub-pixel farther away from the scanning driving unit (for example, a sub-pixel in the last column). This phenomenon is called direct current voltage drop (IR Drop).

Because the voltage input to the sub-pixels by the scanning driving unit is related to current flowing through each sub-pixel, the IR drop will cause differences in values of current flowing through the sub-pixels at different positions, which results in differences in brightness when the AMOLED display device displays. For example, when all light-emitting elements of a row of sub-pixels emit light, brightness displayed by the row of sub-pixels may decrease sequentially from left to right, which results a phenomenon of brightness difference called mura phenomenon. This phenomenon will lead to a decrease in quality of a display picture, thereby causing adverse effects on quality and display effect of the display device.

In research, an inventor of the present application found that: in response to current development trend of large size, high transmittance and high brightness for display device, some display devices may have a problem of too high temperature during displaying, and it is difficult for the display devices to reduce influence of temperature rising due to resistance while improving pixel brightness and reducing the direct current voltage drop (IR Drop). In addition, because the sub-pixel pitch in the display devices is usually small, a light leakage phenomenon may occur between adjacent sub-pixels in an arrangement direction, which may cause poor display effect of the display device.

An embodiment of the present disclosure provides a display substrate and a manufacturing method thereof, and a display device.

A display substrate provided by an embodiment of the present disclosure includes: a base substrate, a plurality of sub-pixels and a defining pattern. The plurality of sub-pixels are on the base substrate, and each of at least part of the plurality of sub-pixels comprises a light-emitting element, the light-emitting element comprises a light-emitting functional layer, a first electrode and a second electrode on both sides of the light-emitting functional layer in a first direction, the first electrode is between the light-emitting functional layer and the base substrate, and the first direction is perpendicular to the base substrate. The pixel-defining pattern includes a plurality of openings and a defining portion that surrounds the plurality of openings, at least a portion of the light-emitting element is in the opening. The defining portion includes at least one cavity, and the cavity surrounds at least one opening. The display substrate further includes a first filling structure, and the first filling structure is in the cavity, and a surface, away from the base substrate, of the first filling structure is farther away from the base substrate than a surface, away from the base substrate, of at least a portion of the light-emitting functional layer in the opening.

The display substrate provided by the embodiment of the present disclosure can reduce a risk of light leakage and color cross-talk between adjacent sub-pixels by providing at least one cavity in the defining portion of the pixel-defining pattern and arranging the first filling structure in the cavity, and effectively reduce the temperature of the defining portion during a display process, thereby reducing phenomena such as poor display effect because of too high temperature of the display substrate.

The display substrate and the manufacturing method thereof, and the display device provided by the embodiments of the present disclosure will be described below with reference to the accompanying drawings.

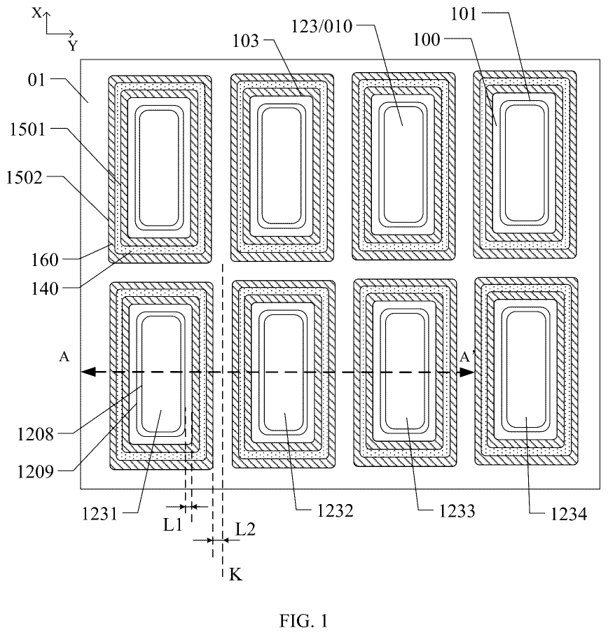

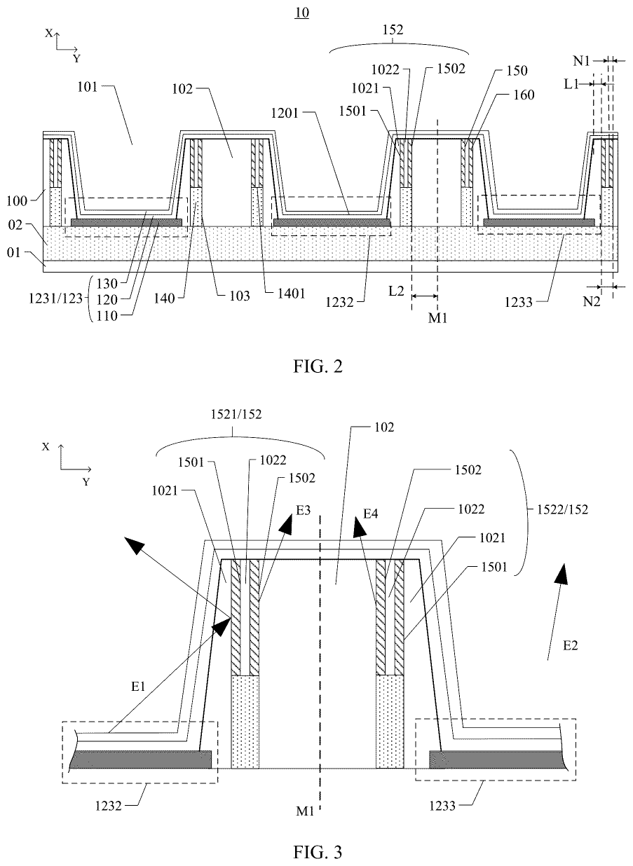

FIG. 1 is a schematic diagram of a partial planar structure of a display substrate provided by an embodiment of the present disclosure. FIG. 2 is a schematic diagram of a partial cross-sectional structure taken in a section line AA′ illustrated in FIG. 1.

As illustrated in FIG. 1 and FIG. 2, the display substrate 10 includes a base substrate 01 and a plurality of sub-pixels 010 on the base substrate 01. Each of at least part of the plurality of sub-pixels 010 includes a light-emitting element 123, the light-emitting element 123 includes a light-emitting functional layer 120, a first electrode 110 and a second electrode 130, the first electrode 110 and the second electrode 130 are on both sides of the light-emitting functional layer 120 in a first direction X, and the first electrode 110 is between the light-emitting functional layer 120 and the base substrate 01. A contour of each sub-pixel 010 in FIG. 1 is a contour of a light-emitting region of the light-emitting element 123. The first direction X can be a direction perpendicular to the base substrate 01.

For example, as illustrated in FIG. 1 and FIG. 2, the light-emitting element 123 may be an organic light-emitting element. For example, each sub-pixel 010 in a display region includes a light-emitting element 123. For example, a plurality of light-emitting elements 123 include part of light-emitting elements 123 emitting light of the same color and part of light-emitting elements 123 emitting light of different colors, and the light-emitting elements 123 emitting light of the same color and the light-emitting elements 123 emitting light of different colors can share the second electrode 130 and the light-emitting functional layer 120, the light-emitting functional layer 120 can be a common layer, and the second electrode 130 can also be a common layer.

For example, as illustrated in FIG. 1 and FIG. 2, the light-emitting functional layers 120 of the sub-pixels 010 emitting light of different colors can emit light of the same color, for example, white light, and the light of the same color can be converted into light of different colors after passing through a color filter.

For example, the sub-pixels 010 may include a red sub-pixel, a green sub-pixel, a blue sub-pixel and a white sub-pixel, the red sub-pixel includes a red light-emitting element 1231, and light emitted by the red light-emitting element 1231 can be converted into red light after passing through a red color film: the green sub-pixel includes a green light-emitting element 1232, and light emitted by the green light-emitting element 1232 can be converted into green light after passing through a green color filter: the blue sub-pixel includes a blue light-emitting element 1233, and light emitted by the blue light-emitting element 1233 can be converted into blue light after passing through a blue color filter: the white sub-pixel includes a white light-emitting element 1234, and light emitted by the white light-emitting element 1234 can be converted into white light after passing through a white color film.

For example, as illustrated in FIG. 1 and FIG. 2, the display substrate 10 may further includes a color filter layer (as illustrated in FIG. 7) on a side of the light-emitting element 123 away from the base substrate 01. For example, the color filter layer includes a portion in a light-emitting region and a portion in a region between adjacent light-emitting regions. For example, a portion of the color filter layer corresponding to the red light-emitting element 1231 in the color filter layer can be a red color filter: a portion of the color filter layer corresponding to the green light-emitting element 1232 in the color filter layer can be a green color filter: a portion of the color filter layer corresponding to the blue light-emitting element 1233 can be a blue color filter: a portion of the color filter layer in the color filter layer corresponding to the white light-emitting element 1234 can be a white color filter. Of course, the embodiments of the present disclosure are not limited thereto, the color filter layer may be on another substrate, which is opposite to the display substrate.

For example, as illustrated in FIG. 1 and FIG. 2, the first electrode 110 may be an anode, and the second electrode 130 may be a cathode. For example, the cathode can be formed of a material with high conductivity and low work function, for example, the cathode can be made of a metal material. For example, the anode may be formed of a transparent conductive material with a high work function. For example, the second electrode 130 may include one film layer or two film layers. For example, a material of the second electrode 130 may include indium oxide (for example, InOₓ), but is not limited thereto. For example, the first electrode 110 is a reflective electrode, and the second electrode 130 is a transparent electrode. For example, light emitted by the light-emitting functional layer 120 can exit from a side of the second electrode 130 away from the first electrode 110, for example, the display substrate 10 can have at least part of characteristics of a “top-emitting” structure.

As illustrated in FIG. 1 and FIG. 2, the display substrate further includes a pixel-defining pattern 100. The pixel-defining pattern 100 includes a plurality of openings 101 and a defining portion 102 that surrounds the plurality of openings 101, at least a portion of the light-emitting element 123 is in the opening 101. For example, the opening 101 of the pixel-defining pattern 100 is configured to define the light-emitting region of the light-emitting element 123. For example, a plurality of light-emitting elements 123 may be arranged in one-to-one correspondence with a plurality of openings 101.

As illustrated in FIG. 1 and FIG. 2, the first electrode 110 of the light-emitting element 123 is on a side of at least of the defining portion 102 close to the base substrate 01, the opening 101 is configured to expose the first electrode 110, and at least a portion of the first electrode 110 exposed is in contact with the light-emitting functional layer 120 of the light-emitting element 123. For example, in the case where the light-emitting functional layer 120 is in the opening 101 of the pixel-defining pattern 100, the first electrode 110 and the second electrode 130 on both sides of the light-emitting functional layer 120 can drive the light-emitting functional layer 120 in the opening 101 of the pixel-defining pattern 100 to emit light.

For example, as illustrated in FIG. 2, a driving structure layer 02 is further provided on a side of the first electrode 110 facing the base substrate 01, for example, the driving structure layer 02 includes pixel circuits electrically connected to the light-emitting elements 123, signal lines and various insulation layers and so on.

It should be noted that a size of the opening 101 illustrated in FIG. 1 is only schematic, and the shape, the size, and the relative position of the light-emitting region of the light-emitting element 123 of each sub-pixel 010 can be set according to a design requirement, which are not limited by the embodiments of the present disclosure. An arrangement of the plurality of sub-pixels 010 in the display substrate 10 illustrated in FIG. 2 is only schematic, and embodiments of the present disclosure are not limited thereto. For example, different pixel arrangements can be selected according to an actual layout design requirement, for example, a “diamond arrangement”, a “diamond-like arrangement”, or a “GGRB arrangement” can be selected, which are not limited in the embodiments of the present disclosure.

As illustrated in FIG. 1 and FIG. 2, the defining portion 102 includes at least one cavity 103, and the cavity 103 surrounds at least one opening 101. The display substrate 10 further includes a first filling structure 140 in the cavity 103.

In the first direction X, a surface 1401, away from the base substrate 01, of the first filling structure 140 is farther away from the base substrate 01 than a surface 1201, away from the base substrate 01, of at least a portion of the light-emitting functional layer 120 in the opening 101. When at least a part of light emitted by the light-emitting functional layer 120 reaches the first filling structure 140 in the cavity 103, this part of the light can be blocked by the first filling structure 140 outside a light-emitting range of an adjacent light-emitting element 123. For example, this part of the light can be prevented from reaching the color filter layer corresponding to the adjacent light-emitting element 123. For example, when two adjacent light-emitting elements 123 are configured not to emit light at the same time, with such arrangement, the risk of light leakage and color cross-talk between adjacent sub-pixels can be effectively reduced.

For example, the first filling structure 140 may include a light-shielding material, but is not limited thereto. For example, the first filling structure 140 may further have a good thermal conductivity, so that at least part of heat generated by the defining portion 102 during a light-emitting process of the light-emitting element 123 can be exported. For example, the heat can be exported to a side of the defining portion 102 close to the base substrate 01, and then gradually diffused outside of the display substrate 10, which is not limited thereto. Therefore, the first filling structure 140 arranged in this manner can reduce heat in the defining portion 102, thereby reducing a risk of poor display effect of the display substrate 10 because of too high temperature of the defining portion 102.

For example, as illustrated in FIG. 1, the defining portion 102 includes a first contour portion 1208 and a second contour portion 1209, and the first contour portion 1208 may be a boundary of the light-emitting region of the light-emitting element 123 exposed by the defining portion 102. As illustrated in FIG. 2, a partial cross-sectional structure of the defining portion 102 taken in the section line AA′ illustrated in FIG. 1 is roughly a “trapezium”, and an “upper bottom” of the “trapezium” is further away from the base substrate 01 than a “lower bottom” of the “trapezium”. For example, a portion of a surface of the defining portion 102 which is away from and parallel or approximately parallel to the base substrate 01 can be considered as the “upper bottom” of the “trapezium”. The second contour portion 1209 illustrated in FIG. 1 can be an orthographic projection of an edge of the “upper bottom” of the “trapezium” on the base substrate 01. FIG. 2 takes that an included angle between the “upper bottom” and a “bevel” of the “trapezium” is a sharp angle as an example, but it is not limited thereto. For example, the included angle between the “upper bottom” and the “bevel” of the “trapezium” can be a rounded fillet, and the second contour portion 1209 can be an orthographic projection of a boundary of a planar portion of the “upper bottom”.

For example, as illustrated in FIG. 1, the cavity 103 in the defining portion 102 surrounds the light-emitting element 123, and an orthographic projection of the cavity 103 on the substrate 01 is closed and independent ring-shape. For example, the defining portion 102 further includes a plurality of grooves 150, and the plurality of grooves 150 includes a first groove portion 1501 and a second groove portion 1502. Orthographic projections of the first groove portion 1501 and the second groove portion 1502 (described in detail later) in each defining portion 102 on the base substrate 01 are both closed and independent ring-shape, and the first groove portion 1501 is closer to the light-emitting region of the light-emitting element 123 than its immediately adjacent second groove portion 1502. For example, an orthographic projection of the first groove portion 1501 on the base substrate 01 has a smaller area than that of an orthographic projection of the second groove portion 1502 on the base substrate 01, but it is not limited thereto. For example, first groove portions 1501 respectively next to two adjacent light-emitting elements 123 are not connected to each other, and second groove portions 1502 respectively next to two adjacent light-emitting elements 123 are not connected to each other, but it is not limited thereto.

As mentioned above, in the display substrate 10 provided by the embodiment of the present disclosure, at least one cavity 103 is arranged in the definition portion 102 of the pixel-defining pattern 100, and the first filling structure 140 is arranged in the cavity 103, the risk of light leakage and color cross-talk between adjacent sub-pixels can be reduced, and the temperature of the defining portion during a display process can be effectively reduced, thereby the phenomena such as poor display effect due to too high temperature of the display substrate can be reduced.

The cavity 103 in the above-mentioned defining portion 102 can refer to a cavity filled to the full by the first filling structure 140, and the cavity 103 can only be in the defining portion 102 without communicating with a space outside the defining portion 102, for example, the cavity 103 is not communicated with the opening surrounded by the defining portion 102. For example, the cavity 103 can be a groove formed by a surface of the defining portion 102 close to the base substrate 01 being recessed towards interior of the defining portion 102, and the groove is filled to the full by the first filling structure 140.

For example, as illustrated in FIG. 2, the first filling structure 140 may include a material having a thermal conductivity K satisfying 350<K<550, to have a good thermal conductivity and be beneficial to exporting heat in the defining portion 102. For example, the thermal conductivity K of the material selected for the first filling structure 140 satisfies at least one of 380<K<450, 400<K<460, 420<K<480, 430<K<500 and 440<K<530, which is not limited in the embodiments of the present disclosure.

For example, the material of the first filling structure 140 may include metal, for example, silver, but is not limited thereto. For example, the material of the first filling structure 140 may further include copper, or other metal or alloy materials with good thermal conductivity and can be easily processed, which can be selected according to a design requirement.

For example, as illustrated in FIG. 1 and FIG. 2, a minimum distance in a second direction Y between an edge of a surface of the defining portion 102 at a side away from the base substrate 01 and an edge of an orthographic projection of the first filling structure 140 on the base substrate 01, which are adjacent to each other, is a first distance L1, and the second direction Y is a direction perpendicular to an extending direction of the edges. A distance between a center line K of an orthographic projection of the defining portion 102 on the display substrate 01 and an orthographic projection of a first filling structure 140 next to the center line K on the display substrate 01 is a second distance L2, the first distance L1 is smaller than the second distance L2, and the center line K is parallel to an extending direction of the defining portion 102. For example, the second direction Y is perpendicular to an extending direction of the defining portion 102, and the second direction Y is perpendicular to the first direction X.

For example, as illustrated in FIG. 2, an orthographic projection of an edge of the first filling structure 140 on the base substrate 01 and an orthographic projection of an edge of the defining portion 102 on the base substrate 01 that are adjacent to each other can be an edge of the “upper bottom” of the above-mentioned “trapezium” and an edge of the first filling structure 140 close to the edge of the “upper bottom” of the “trapezium” respectively, a minimum distance between the edge of the “upper bottom” of the “trapezium” and the edge of the first filling structure 140 close to the edge of the “upper bottom” of the “trapezium” in the second direction Y may be the first distance L1 as illustrated in FIG. 1 and FIG. 2. For example, the center line K of the orthographic projection of the defining portion 102 on the base substrate 01 may be a center line K of an orthographic projection of a part of the surface of the defining portion 102 away from the base substrate 01 that is parallel or substantially parallel to the base substrate 01 on the base substrate 01, that is, an orthographic projection of a center plane M1 of the “upper bottom” of the “trapezium” perpendicular to the base substrate 01 on the base substrate 01, a distance between an orthographic projection of the filling structure 140 immediately adjacent to the center line K on the base substrate 01 and the center line K may be the second distance L2 as illustrated in FIG. 1 and FIG. 2, and the second distance L2 is greater than the first distance L1.

With such arrangement, the first filling structure 140 can be as close as possible to the light-emitting region of the light-emitting element 123, so that light from the light-emitting region can be effectively blocked from a light-emitting region of an adjacent light-emitting element 123, to reduce the risk of light leakage and color cross-talk.

For example, in the second direction Y, the ratio of the first distance L1 between the adjacent edges of the orthographic projections of the first filling structure 140 and the defining portion 102 on the base substrate 01 to the second distance L2 between the center line K of the orthographic projection of the defining portion 102 on the display substrate 01 and the orthographic projection of a first filling structure 140 next to the center line K on the display substrate 01 is at least one of 1/7˜⅙, ⅙˜⅕, ⅕˜¼, ⅕˜⅓, but is not limited thereto, so that a blocking efficiency of the first filling structure 140 to the light from the light-emitting region of the light-emitting element 123 next to it can be improved.

For example, as illustrated in FIG. 2, two cavities 103 are arranged between two adjacent sub-pixels that are arranged in the second direction Y, and orthographic projections of the two cavities 103 on the base substrate 01 are on two side of the center line K, respectively. That is, two cavities 103 on both sides of the central line K may be arranged in the defining portion 102 between two adjacent sub-pixels. Because each cavity 103 is provided with the first filling structure 140, light emitted from two light-emitting elements 123 next to the defining portion 102 are respectively blocked, so that the risk of light leakage and color cross-talk between adjacent sub-pixels can be reduced.

For example, as illustrated in FIG. 2, in the second direction Y, the two cavities 103 between two adjacent sub-pixels may be distributed symmetrically or approximately symmetrically with respect to the center line K between the two cavities 103, to balance a blocking effect of the two cavities 103 on light emitted by the light-emitting elements 123 next to the two cavities 103 respectively, bring convenience for manufacturing. Of course, the embodiments of the present disclosure include but are not limited thereto. For example, the two cavities 103 between two adjacent sub-pixels may have different distances from the center line K between the two cavities 103, so that the two cavities 103 have different blocking effects on the light emitted by the light-emitting elements 123 adjacent to the two cavities 103 respectively, which can be set according to a design requirement, which is not limited in the embodiments of the present disclosure.

For example, as illustrated in FIG. 1 and FIG. 2, light emitted by the light-emitting element 123 between two adjacent defining portions 102 is emitted along a boundary of the light-emitting region of the light-emitting element 123, and a partial region of the opening 101 defined by the defining portion 102 close to the substrate 01 is close to the light-emitting element 123, therefore light in this partial region of the opening 101 has a higher intensity and is more likely to be emitted into the light-emitting region of the adjacent light-emitting element 123. For example, a size of the first filling structure 140 in the first direction X can be no larger than ½ of the maximum size of the defining portion 102 in the first direction X, so that the light in this partial region of the opening 101 defined by the defining portion 102 close to the base substrate 01 can be effectively blocked, to reduce the risk of light leakage and color cross-talk between adjacent sub-pixels 010.

For example, as illustrated in FIG. 2, the ratio of the size of the first filling structure 140 in the first direction X to the maximum size of the defining portion 102 in the first direction X can be at least one of ¼˜½, ¼˜⅓ and ⅓˜½, but it is not limited thereto. For example, the first filling structure 140 can block light which has an included angle of 2° ˜ 50° with a surface of the light-emitting functional layer 120 away from the base substrate 01 from entering the light-emitting region of the adjacent light-emitting element 123, but it is not limited thereto. For example, the above-mentioned range of the included angle can be at least one of 5°˜45°, 8°˜5°, 10°˜18°, 20°˜25°, 28°˜32°, 35°˜42° and 45°˜50°, which can be set according to a design requirement.

For example, as illustrated in FIG. 2, in the second direction Y, a size of the first filling structure 140 may be 1/10˜⅙ of the maximum size of the defining portion 102, so that the first filling structure 140 have good blocking effect, and improve a heat exporting efficiency of the first filling structure 140 in the defining portion 102. For example, in the second direction Y, the ratio of the size of the first filling structure 140 to the maximum size of the defining portion 102 may be at least one of ⅛˜⅙, 1/9˜ 1/7, and 1/7˜⅙, which is not limited thereto.

For example, as illustrated in FIG. 2, a surface of the second filling structure 140 close to the base substrate 01 is flush with a bottom surface of the defining portion 102 close to the base substrate 01, so that the light cannot pass between the bottom surface of the defining portion 102 close to the base substrate 01 and the first filling structure 140, and at the same time, it is beneficial to export the heat in the defining portion 102 to a side of the defining portion 102 close to the base substrate 01, and then gradually diffuse to the outside of the display substrate 10.

For example, as illustrated in FIG. 2, at least a portion of the defining portion 102 is on a side of the first electrode 110 in the light-emitting element 123 away from the base substrate 01, and covers a portion of the first electrode 110. For example, an orthographic projection of the first filling structure 140 on the base substrate 01 does not overlap with an orthographic projection of the first electrode 110 on the base substrate 01. For example, a certain distance exists between the orthographic projection of the first electrode 110 on the base substrate 01 and an orthographic projection of the first filling structure 140 in the defining portion 102 covered on the first electrode 110 on the base substrate 01, to prevent the heat in the first filling structure 140 from being directly transferred to the first electrode 110 adjacent to it, thereby a risk of occurring failure of the light-emitting element 123 can be reduced.

FIG. 3 is an enlarged schematic diagram of the partial cross-sectional structure illustrated in FIG. 2.

For example, as illustrated in FIG. 1 and FIG. 2, at least one groove 150 in the defining portion surrounds the opening 101, and the groove 150 is on a side of the cavity 103 away from the base substrate 01. The display substrate 10 further includes a second filling structure 160 in the groove 150, the second filling structure 160 includes a light-transmitting material, and a material of the second filling structure 160 is different from a material of the defining portion 102. Therefore, the second filling structure 160 and the defining portion 102 have different refractive indices.

For example, as illustrated in FIG. 2 and FIG. 3, the plurality of grooves 150 include a first groove portion 1501 and a second groove portion 1502, and the defining portion 102 includes a first defining portion 1021 and a second defining portion 1022, and in the second direction Y, the first defining portion 1021, the second filling structure 160 in the first groove portion 1501, the second defining portion 1022, and the second filling structure 160 in the second groove portion 1502 are arranged in sequence to form a light filtering structure 152. For example, as illustrated in FIG. 3, in the light filtering structure 152, the first defining portion 1021 is farther away from the center line K of the orthographic projection of the defining portion 102 on the base substrate 01 than the second defining portion 1022, and the first groove portion 1501 is farther away from the center line K than the second groove portion 1502.

With such arrangement, as illustrated in FIG. 2 and FIG. 3, because the first defining portion 1021 and the second defining portion 1022 are made of the same material, the light filtering structure 152 can be used as a distributed Bragg reflection (DBR) structure. According to a structural characteristic of the DBR, an alternate arrangement of medias with two refractive indices (for example, the defining portion 102 and the second filling structure 160 in this application) can reflect light, and a reflectivity of the DBR structure is relatively high, for example, it can reach 98%˜99%; at the same time, compared with some metal mirror structures, the DBR structure has no problem of light absorption. Moreover, the light exiting from the light filtering structure 152 of the DBR structure has a specific wavelength or is within a specific wavelength range.

For example, as illustrated in FIG. 3, when light E1 emitted by a light-emitting element 1232 reaches a light filtering structure 152 immediately adjacent to the light-emitting element 1232 in the defining portion 102, a part of light can be reflected on a surface of the light filtering structure 152, and then the reflected light reaches the color filter layer opposite to the light-emitting element 1232 to be converted into light of a corresponding color. For example, a small part of light may enter the light filtering structure 152 and be refracted in the light filtering structure 152, and then exit from the defining portion 102, for example, exiting light may be light E3 as illustrated in FIG. 3. For example, when a sub-pixel where the light-emitting element 1232 is located and a sub-pixel where an adjacent light-emitting element 1233 is located are sub-pixels of different colors, a part of the light E1 is refracted in the light filtering structure 152 to emit light E3, and the light E3 can enter the color filter layer corresponding to the light-emitting element 1233 together with the light E2, to from light corresponding to the light-emitting element 1233.

Therefore, by arranging the light filtering structure 152 in the defining portion 102 between two adjacent light-emitting elements, on the one hand, the light emitted by the light-emitting element 123 can be reflected, and the reflected light can enter into the color filter layer corresponding to the light-emitting element 123: on the other hand, the light filtering structure 152 can further make light with a specific wavelength of the light emitted by the light-emitting element 123 enter the color filter layer corresponding to the adjacent light-emitting element 123 after being refracted, and further enhance light-emitting brightness of the adjacent light-emitting elements 123, which improves a utilization rate of the light, and reduces effect of light leakage between adjacent sub-pixels.

For example, as illustrated in FIG. 2, the first defining portion 1021 in the light filtering structure 152, the second filling structure 160 in the first groove portion 1501, the second defining portion 1022, and the second filling structure 160 in the second groove portion 160 each satisfies:

$$d = λ / ( 4 * n )$$

in this formula, d represents a thickness of any one of the first defining portion 1021, the second filling structure 160 in the first groove portion 1501, the second defining portion 1022, and the second filling structure 160 in the second groove portion 1502 in the second direction Y, λ represents a wavelength of incident light, n represents a refractive index of any one of the first defining portion 1021, the second filling structure 160 in the first groove portion 1501, the second defining portion 1022, and the second filling structure 160 in the second groove portion 1502.

For example, as illustrated in FIG. 2 and FIG. 3, the light filtering structure 152 has the characteristics of the above-mentioned DBR structure. For example, in the case where the materials of the first defining portion 1021, the second filling structure 160 in the first groove portion 1501, the second defining portion 1022, and the second filling structure 160 in the second groove portion 1502 of the light filtering structure 152 have been selected, the thickness of each film layer in the light filtering structure 152 in the second direction Y is related to a wavelength of light emitted from the light filtering structure 152. For example, the wavelength of the light emitted by the light filtering structure 152 corresponds to a light-emitting color of the sub-pixel 010 whose light-emitting brightness is enhanced, that is, the wavelength of the light emitted by the light filtering structure 152 is a wavelength that is corresponding to a light-emitting color of the sub-pixel 010 whose light-emitting brightness is enhanced.

For example, taking a structure of the display substrate 10 illustrated in FIG. 3 as an example, a sub-pixel where the light-emitting element 1232 is located is a red sub-pixel, and the sub-pixel where the light-emitting element 1233 is located is a blue sub-pixel, because a color of the color filter layer corresponding to the light-emitting element 1233 is blue, therefore, in a process of determining thicknesses of the first defining portion 1021, the second filling structure 160 in the first groove portion 1501, the second defining portion 1022, and the second filling structure 160 in the second groove portion 1502 of the light filtering structure 1521 according to the above-mentioned formula, the light E1 emitted by the light-emitting element 1232 passes through the light filtering structure 1521 to emit light E3, and the emitted light E3 has a wavelength corresponding to blue light. Similarly, in a process of determining thicknesses of the first defining portion 1021, the second filling structure 160 in the first groove portion 1501, the second defining portion 1022, and the second filling structure 160 in the second groove portion 1502 of the light filtering structure 1522 according to the above-mentioned formula, the light E2 emitted by the light-emitting element 1233 passes through the light filtering structure 1522 to emit light E4, and the emitted light E4 has a wavelength corresponding to red light.

Therefore, by arranging the light filtering structure 152 with an appropriate film thickness in the defining portion 102, on the one hand, light in a partial wavelength range of the light emitted by the light-emitting element 123 can be reflected on a surface of the light filtering structure 152, and then reaches the color filter layer corresponding to the light-emitting element 123: on the other hand, in the case where each film layer in the light filtering structure 152 has a certain thickness and a certain refractive index, the light enters the light filtering structure 152 and is refracted, and exited light has a specific wavelength or has a wavelength within a specific wavelength range, so that the light filtering structure 152 can “screen out” light with specific wavelength, and a color of the light with the specific wavelength can be the same as a color of the color filter layer corresponding to the light-emitting element 123 whose light-emitting brightness is enhanced, therefore, the light filtering structure 152 can effectively reduce the influence of light leakage between adjacent sub-pixels.

It should be noted that in the case where two adjacent light-emitting elements are configured not to emit light at the same time, because light emitted by each light-emitting element, refracted by the light filtering structure 152 and then entering the light-emitting region of an adjacent light-emitting element is relatively small, (for example, at least 98% of the light emitted by the light-emitting element is reflected on a surface of the light filtering structure 152), this part of the light entering the color filter layer corresponding to the adjacent light-emitting element is not enough to reach a light intensity that is required by the adjacent light-emitting element alone, so this part of the light can enhance a light-emitting brightness of the adjacent light-emitting element without affecting the light-emitting of the light-emitting element configured to not emit light.

For example, as illustrated in FIG. 2 and FIG. 3, at least two light filtering structures 152 are arranged between two adjacent sub-pixels that are arranged in the second direction Y, so that the light emitted by the light-emitting elements 123 of the two adjacent sub-pixels can be reflected on surfaces of light filtering structures 152 next to them respectively, and at the same time, the light emitted by the light-emitting element 123 in each sub-pixel of the two adjacent sub-pixels can be refracted by the light filtering structure 152 next to it, and enters into the color filter layer corresponding to the light-emitting element 123 of the other sub-pixel: therefore, the light-emitting brightness of the light-emitting elements 123 in the two adjacent sub-pixels can be enhanced.

For example, as illustrated in FIG. 2, an orthographic projection of the first groove portion 1501 on the base substrate 01 and an orthographic projection of the second groove portion 1502 on the base substrate 01 overlap with an orthographic projection of a same cavity 103 on the base substrate 01. For example, an area of the orthographic projection of the first groove portion 1501 on the base substrate 01 and the orthographic projection of the second groove portion 1502 on the base substrate 01 overlapping with an orthographic projection of an immediately adjacent cavity 103 on the base substrate 01 is at least one of 60%˜98%, 70%˜95%, 75%˜90%, 80%˜95%, and 85%˜90% of an area of the orthographic projection of the first groove portion 1501 on the base substrate 01 and the orthographic projection of the second groove portion 1502 on the base substrate 01, but is not limited thereto. For example, the orthographic projection of the first groove portion 1501 on the base substrate 01 and the orthographic projection of the second groove portion 1502 on the base substrate 01 may fall within the orthographic projection of the same cavity 103 on the base substrate 01, which may be set according to a design requirement.

With such arrangement, as illustrated in FIG. 2, a light filtering structure 152 can cooperate with a first filling structure 140 immediately adjacent to the light filtering structure 152. While the first filling structure 140 blocks light, the light filtering structure 152 immediately adjacent to the first filling structure 140 can reflect light and enhance light-emitting brightness of an adjacent light-emitting element 123.

For example, as illustrated in FIG. 2, a surface of the second filling structure 160 close to the base substrate 01 is flush with at least a portion of a surface of the first filling structure 140 away from the base substrate 01. Therefore, the surface of the second filling structure 160 close to the base substrate 01 can connect with the least a portion of the surface of the first filling structure 140 away from the base substrate 01, so that the light emitted by the light-emitting element 123 cannot directly pass between the second filling structure 160 and first filling structure 140 which are immediately adjacent to each other, thereby reducing the risk of light leakage.

For example, as illustrated in FIG. 2, a surface of the second filling structure 160 away from the base substrate 01 is partially flush with the surface of the defining portion 102 away from the base substrate 01, so that the second filling structure 160 has a sufficient size in the first direction X, and the light emitted by the light-emitting element 123 cannot pass directly between the surface of the second filling structure 160 away from the base substrate 01 and the surface of the defining portion 102 away from the base substrate 01, thereby reducing the risk of light leakage.

For example, as illustrated in FIG. 2, in the second direction Y, a size N1 of the second filling structure 160 is smaller than a size N2 of the first filling structure 140, so that the light filtering structure 152 can better cooperate with adjacent the first filling structure 140, which is beneficial to a structure arrangement.

For example, as illustrated in FIG. 2, in the light filtering structure 152, a refractive index n1 of the first defining portion 1021 and a refractive index n2 of the second defining portion 1022 satisfy: 1.43≤n1≤1.47 and 1.43≤n2≤1.47, respectively. For example, in an embodiment of the present disclosure, the refractive index n1 of the first defining portion 1021 may be equal to the refractive index n2 of the second defining portion 1022, but it is not limited thereto. For example, at least one of the refractive index n1 of the first defining portion 1021 and the refractive index n2 of the second defining portion 1022 may be at least one of 1.4˜1.5, 1.42˜1.47, and 1.45˜1.46, but is not limited thereto. For example, at least one of the first defining portion 1021 and the second defining portion 1022 may adopt at least one of polyimide, acrylic or polyethylene glycol terephthalate, but is not limited thereto.

For example, as illustrated in FIG. 2, the second filling structure 160 adopts a material different from that of the first defining portion 1021 and the second defining portion 1022. For example, the material of the second filling structure 160 may include silicon nitride, and its refractive index is greater than the refractive index n1 of the first defining portion 1021 and the refractive index n2 of the second defining portion 1022. For example, in the light filtering structure 152, a refractive index n3 of the second filling structure 160 in the first groove portion 1501 and a refractive index n4 of the second filling structure 160 in the second groove portion 1502 respectively satisfy: 1.83≤n3≤1.87, 1.83≤n4≤1.87. For example, in an embodiment of the present disclosure, the material of the second filling structure 160 in the first groove portion 1501 is the same as the material of the second filling structure 160 in the second groove portion 1502, but it is not limited thereto. For example, the refractive index of the second filling structure 160 may be at least one of 1.83˜1.86, 1.84˜1.86, and 1.85˜1.87, but is not limited thereto.

For example, as illustrated in FIG. 2, in the light filtering structure 152, a thickness d1 of the first defining portion 1021 in the second direction Y may be greater than a thickness d3 of the second filling structure 160 in the first groove portion 1501 in the second direction Y. This is because, in the case where the refractive index n1 of the first defining portion 1021 and the refractive index n2 of the second defining portion 1022 are both smaller than the refractive index of the second filling structure 160, and the wavelength of incident light is selected, according to the formula d=λ/(4*n), the thickness of each film layer in the light filtering structure 152 is negatively correlated with the refractive index.

For example, as illustrated in FIG. 2, in the light filtering structure 152, the thickness d1 of the first defining portion 1021 and the thickness d2 of the second defining portion 1022 can respectively satisfy: 75 nm≤d1≤130 nm, 75 nm≤d2≤130 nm.

For example, as illustrated in FIG. 2, in the case where the refractive index n1 of the first defining portion 1021 is equal to the refractive index n2 of the second defining portion 1022, and are both in a range of 1.43˜1.47, for blue light with a wavelength of 460 nm˜470 nm, the thickness d1 of the first defining portion 1021 and the thickness d2 of the second defining portion 1022 can be both in a range of 78 nm˜83 nm, for example, it can be at least one of 80 nm˜83 nm, 81 nm˜82 nm and 78 nm˜82 nm, but is not limited thereto. For example, for red light with a wavelength of 620 nm˜720 nm, the thickness d1 of the first defining portion 1021 and the thickness d2 of the second defining portion 1022 can be both in a range of 105 nm˜126 nm, for example, it can be at least one of 105 nm˜108 nm, 110 nm˜125 nm and 113 nm˜122 nm, but is not limited thereto. For example, for green light with a wavelength of 510 nm˜560 nm, the thickness d1 of the first defining portion 1021 and the thickness d2 of the second defining portion 1022 can be both in a range of 86 nm˜98 nm, for example, it can be at least one of 86 nm˜89 nm, 88 nm˜95 nm and 90 nm˜97 nm, but is not limited thereto.

For example, as illustrated in FIG. 2, in the light filtering structure 152, the thickness d3 of the second filling structure 160 in the first groove portion 1501 and the thickness d4 of the second filling structure 160 in the second groove portion 1502 respectively satisfy: 60 nm≤d1≤100 nm, 60 nm≤d2≤100 nm.

For example, as illustrated in FIG. 2, in the case where the refractive index n3 of the second filling structure 160 in the first groove portion 1501 is equal to the refractive index n4 of the second filling structure 160 in the second groove portion 1502, and are both in a range of 1.83˜1.87, for the blue light with the wavelength of 460 nm˜470 nm, the thickness d3 of the second filling structure 160 in the first groove portion 1501 and the thickness d4 of the second filling structure 160 in the second groove portion 1502 can be both in a range of 61 nm˜65 nm, for example, it can be at least one of 61 nm˜62 nm, 61 nm˜64 nm and 63 nm˜65 nm, but is not limited thereto. For example, for the red light with the wavelength of 620 nm˜720 nm, the thickness d3 of the second filling structure 160 in the first groove portion 1501 and the thickness d4 of the second filling structure 160 in the second groove portion 1502 can be both in a range of 82 nm˜99 nm, for example, it can be at least one of 82 nm˜84 nm, 85 nm˜96 nm, and 95 nm˜98 nm, but is not limited thereto. For example, for the green light with the wavelength of 510 nm˜560 nm, the thickness d3 of the second filling structure 160 in the first groove portion 1501 and the thickness d4 of the second filling structure 160 in the second groove portion 1502 can be both in a range of 68 nm˜77 nm, for example, it can be at least one of 68 nm˜69 nm, 69 nm˜74 nm, and 70 nm˜76 nm, but is not limited thereto.

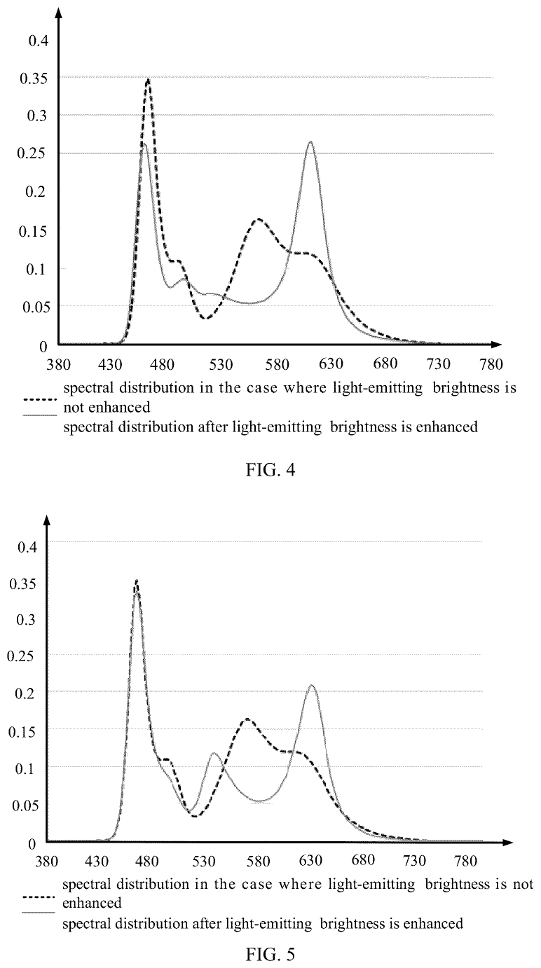

FIG. 4 is a spectral schematic diagram after light-emitting brightness of a light-emitting element in a display substrate illustrated by an embodiment of the present disclosure is enhanced.

For example, as illustrated in FIG. 4, according to a law of spectral distribution, for the blue light with the wavelength of about 460 nm˜480 nm, the red light with the wavelength of about 620 nm˜630 nm, and the green light with the wavelength of about 530 nm˜560 nm, a black dotted line represents a local spectral distribution in the case where the light-emitting brightness of the light-emitting element in the display substrate is not enhanced, and a gray solid line represents a local spectral distribution after the light-emitting brightness of the light-emitting element in the display substrate is enhanced. According to the black dotted line, it can be seen that an energy peak value of the blue light is larger, an energy peak value corresponding to the green light is next, and an energy peak value corresponding to the red light is the smallest. A portion of the black dotted line near the energy peak value corresponding to the blue light illustrates an obvious peak, a portion of the black dotted line near the energy peak value corresponding to the green light has a relatively flat trend, and a portion of the black dotted line near the energy peak value corresponding to the red light illustrates the flattest trend. As can be seen from the gray solid line in FIG. 4, after adjusting the light filtering structure in the display substrate according to a design requirement, the energy peak value corresponding to the red light has been greatly improved, and is close to the energy peak value of the blue light: at the same time, compared with the black dotted line, a portion of the gray solid line near an energy peak value corresponding to the red light illustrates a obvious peak. Therefore, it can be seen from FIG. 4 that the light-emitting intensity of the sub-pixel configured to emit red light is significantly enhanced.

FIG. 5 is another spectral schematic diagram after light-emitting brightness of a light-emitting element in a display substrate provided by an embodiment of the present disclosure is enhanced.

For example, as illustrated in FIG. 5, a black dotted line represents a local spectral distribution in the case where the light-emitting brightness of the light-emitting element in the display substrate is not enhanced, and a gray solid line represents a local spectral distribution after the light-emitting brightness of the light-emitting element in the display substrate is enhanced. For example, the black dotted line in FIG. 5 has the same trend and the same peak value as the black dotted line in FIG. 4. After adjusting the light filtering structure in the display substrate according to a design requirement, an energy peak value corresponding to the red light has been improved to a certain extent, and a portion of the gray solid line near the energy peak value corresponding to the red light illustrates an obvious peak. At the same time, compared with the black dotted line, a portion of the gray solid line near the energy peak value corresponding to the green light also presents an obvious peak. Therefore, according to FIG. 5, it can be seen that the portions corresponding to the red light, the blue light and the green light in the gray solid line can all present relatively obvious peaks. For example, regarding a manner of adjusting the light filtering structure, reference may be made to relevant description of the formula corresponding to the light filtering structure in the above-mentioned embodiments, which will not be repeated here.

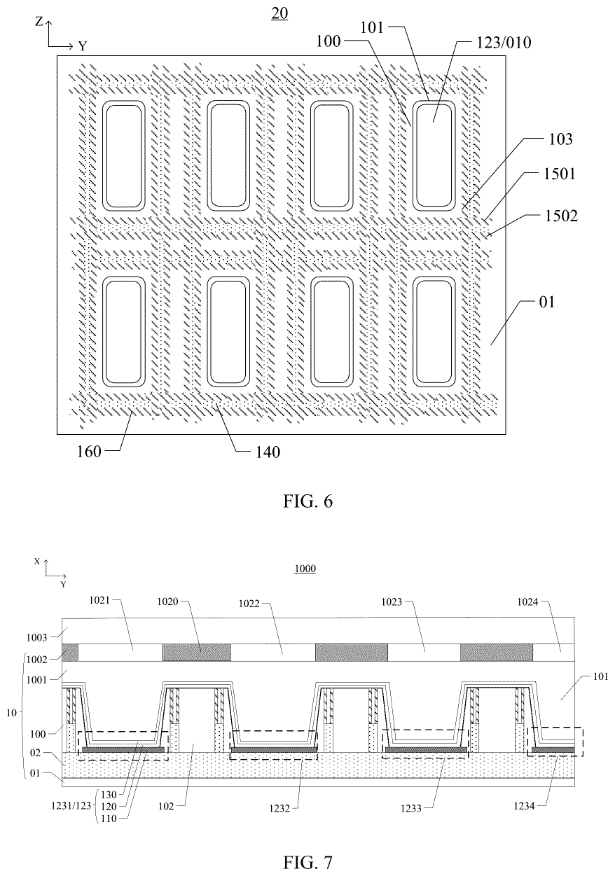

FIG. 6 is a schematic diagram of a partial planar structure of another display substrate provided by an embodiment of the present disclosure.

For example, compared with the display substrate 10 illustrated in FIG. 1, in the display substrate 20 illustrated in FIG. 6, the display substrate 20 includes a plurality of cavities 103 which are continuous and extend in the second direction Y, a plurality of first groove portions 1501 which are continuous and extend in the second direction Y, and a plurality of second groove portions 1502 which are continuous and extend in the second direction Y. As illustrated in FIG. 6, in the second direction Y, cavities 103 immediately adjacent to and on the same side of the light-emitting elements 123 arranged in the same row are connected as a whole, first groove portions 1501 immediately adjacent to and on the same side of the light-emitting elements 123 arranged in the same row are connected as a whole, second groove portions 1502 immediately adjacent to and on the same side of the light-emitting elements 123 arranged in the same row are connected as a whole. In a third direction Z that is perpendicular to the second direction Y, cavities 103 immediately adjacent to and on the same side of the light-emitting elements 123 arranged in the same column are connected as a whole, first groove portions 1501 immediately adjacent to and on the same side of the light-emitting elements 123 arranged in the same column are connected as a whole, second groove portions 1502 immediately adjacent to and on the same side of the light-emitting elements 123 arranged in the same column are connected as a whole. With such arrangement, the cavities 103 immediately adjacent to and on the same side of the light-emitting elements 123 arranged in the same row or in the same column can be formed together, the first groove portions 1501 immediately adjacent to and on the same side of the light-emitting elements 123 arranged in the same row or in the same column can be formed together, and the second groove portions 1502 immediately adjacent to and on the same side of the light-emitting elements 123 arranged in the same row or in the same column can be formed together, so that a manufacturing process can be simplified.

Of course, the embodiments of the present disclosure are not limited thereto, and a shape and a design method of the cavity 103, the first groove portion 1501 and the second groove portion 1502 immediately adjacent to each of the light-emitting element 123 in a part of the light-emitting elements 123 can be set according to an actual design requirement, which is not limited in embodiments of the present disclosure.

For example, in some embodiments of the present disclosure, the cavity 103, the first groove portion 1501 or the second groove portion 1502 can further be provided in a manner of combining the display substrate 10 illustrated in FIG. 1 and the display substrate 20 illustrated in FIG. 6.

For example, referring to FIG. 1 and FIG. 6, in the display substrate 20, an orthographic projection of the cavity 103 immediately adjacent to each of the light-emitting elements 123 of a part of the light-emitting elements 123 on the base substrate 01 may be a closed ring-shape, and the first groove portions 1501 or the second groove portions 1502 that are immediately adjacent to and on the same side of each light-emitting element 123 of the part of the light-emitting elements 123 can be connected as a whole, but is not limited thereto.

For example, referring to FIG. 1 and FIG. 6, in the display substrate 20, an orthographic projection of the cavity 103 immediately adjacent to each of the light-emitting elements 123 of a part of the light-emitting elements 123 on the base substrate 01 may be a closed ring-shape, and the first groove portions 1501 that are immediately adjacent to and on the same side of each light-emitting element 123 of the part of the light-emitting elements 123 can be connected as a whole, and the second groove portions 1502 that are immediately adjacent to and on the same side of each light-emitting element 123 of the part of the light-emitting elements 123 can further be connected as a whole.

For example, referring to FIG. 1 and FIG. 6, in the display substrate 20, the cavities 103 immediately adjacent to and on the same side of a part of the light-emitting elements 123 arranged in the same row or in the same column are connected as a whole, and an orthographic projection of the first groove portion 1501 or the second groove portion 1502 adjacent to each light-emitting element 123 of this part of the light-emitting elements 123 on the base substrate 01 may be a closed ring-shape, but is not limited thereto.

For example, referring to FIG. 1 and FIG. 6, in the display substrate 20, the cavities 103 immediately adjacent to and on the same side of a part of the light-emitting elements 123 arranged in the same row or in the same column are connected as a whole, an orthographic projection of the first groove portion 1501 adjacent to each light-emitting element 123 of this part of the light-emitting elements 123 on the base substrate 01 may be a closed ring-shape, and an orthographic projection of the second groove portion 1502 adjacent to each light-emitting element 123 of this part of the light-emitting elements 123 on the base substrate 01 may be a closed ring-shape.

FIG. 7 is a schematic diagram of a partial cross-sectional structure of a display device provided by at least one embodiment of the present disclosure.

As illustrated in FIG. 7, at least one embodiment of the present disclosure further provides a display device 1000, which includes the display substrate illustrated in any of the above-mentioned embodiments. FIG. 7 schematically illustrates that the display device includes the display substrate 10 illustrated in FIG. 2, but is not limited thereto. As illustrated in FIG. 7, the display substrate 10 further includes an insulating layer 1001 and a color filter layer 1002, the insulating layer 1001 is on a side of the light-emitting element 123 away from the base substrate 01, and the color filter layer 1002 is on a side of the insulating layer 1001 away from the base substrate 01. For example, a material of the insulating layer 1001 may be a metal oxide with a relatively high refractive index to improve light-emitting efficiency, but is not limited thereto.

For example, as illustrated in FIG. 7, the color filter layer 1002 includes a plurality of color filter units and a plurality of black matrix units 1020 that each is between adjacent color filter units. The plurality of color filter units includes a first color unit 1021, a second color unit 1022, a third color unit 1023 and a fourth color unit 1024, the black matrix unit 1020 is configured to block light emitted by a light-emitting element 123. For example, each color filter unit is arranged opposite to a portion of the light-emitting element 123 in an opening 101 of a defining portion 102, for example, the first color unit 1021 is a red color filter corresponding to a red light-emitting element 1231, so that light emitted by the red light-emitting element 1231 can be converted into red light after passing through the first color unit 1021: the second color unit 1022 is a green color filter corresponding to a green light-emitting element 1232, so that light emitted by the green light-emitting element 1232 can be converted into green light after passing through the second color unit 1022; the third color unit 1023 is a blue color filter corresponding to a blue light-emitting element 1233, so that light emitted by the blue light-emitting element 1233 can be converted into blue light after passing through the third color unit 1023; the fourth color unit 1024 is a white color filter corresponding to a white light-emitting element 1234, so that light emitted by the white light-emitting element 1234 can be converted into blue light, but is not limited thereto. For example, the color filter layer 1002 can adopt COE (Color on Encapsulation) technology, and by forming the color film layer 1002 on a side of the light-emitting element 123 away from the base substrate, a contrast ratio of the display device 1000 can be improved.

The red light-emitting element, the green light-emitting element and the blue light-emitting element mentioned above do not mean that each of these light-emitting elements only emits light of a corresponding color, and the light emitted by each of these light-emitting elements can be converted into, for example, red light, green light and blue light after passing through a color filter of a corresponding color.

For example, as illustrated in FIG. 7, the display device 1000 further includes a cover plate 1003 that is on a side of the color filter layer 1002 away from the base substrate 01, for example, the cover plate 1003 has a good packaging performance and can prevent external water and vapor, etc. from invading into the display substrate 10.

In the display device provided by at least one embodiment of the present disclosure, by providing at least one cavity in the definition portion of the pixel-defining pattern of the display substrate, and arranging the first filling structure in the cavity, the risk of light leakage and color cross-talk between adjacent sub-pixels can be effectively reduced, and the temperature of the defining portion during a display process can be effectively reduced, thereby reducing phenomena such as poor display because of too high temperature of the display substrate.

For example, the display device may be a liquid crystal display device and any product or component with a display function such as a television, a digital camera, a mobile phone, a watch, a tablet computer, a notebook computer, a navigator, etc., which is not limited by the embodiment of the present disclosure.

FIG. 8 to FIG. 13 are schematic diagrams showing the processes of a manufacturing method of a display substrate illustrated in at least one embodiment of the present disclosure.

As illustrated in FIG. 8, a manufacturing method of a display substrate provided by at least one embodiment of the present disclosure includes: forming a driving structure layer 02 on a base substrate 01; forming a first conductive thin film on the driving structure layer 02, and patterning the first conductive film to form a first electrode 110 of a light-emitting element 123. For example, the first conductive thin film may include a conductive metal oxide, for example indium tin oxide, but is not limited thereto.

For example, as illustrated in FIG. 8, before forming the driving structure layer 02 on the base substrate 01, the manufacturing method of the display substrate may include preparing the base substrate 01 on a glass carrier plate. For example, the base substrate 01 may be a flexible base substrate. For example, forming the base substrate 01 may include sequentially forming a first flexible material layer, a first inorganic material layer, a semiconductor layer, a second flexible material layer, a second inorganic material layer, etc. on the glass carrier plate arranged in a stacked manner. Materials of the first flexible material layer and the second flexible material layer may be polyimide (PI), polyethylene terephthalate (PET), or surface-treated polymer soft film, etc. For example, materials of the first inorganic material layer and the second inorganic material layer may be silicon nitride (SiNx) or silicon oxide (SiOx) to improve a resistance ability for water and oxygen of the base substrate. A material of the semiconductor layer can be amorphous silicon (a-Si). For example, forming the driving structure layer 02 on the base substrate 01 may include forming a planarization layer, a passivation layer, a buffer layer, a gate insulating layer, an interlayer insulating layer, etc.

For example, as illustrated in FIG. 8, after forming the first electrode 110, the manufacturing method further includes forming a pixel defining layer on the first electrode 110 and patterning the pixel defining layer to form a pixel-defining pattern 100. The pixel-defining pattern 100 includes a plurality of openings 101 and a defining portion 102 that surrounds the plurality of openings 101, the opening 101 exposes at least a part of the first electrode 110.

For example, as illustrated in FIG. 9, the manufacturing method of the display substrate further includes forming a first type of groove 1031 in the defining portion 102, and the first type of groove 1031 surrounds at least one opening 101. For example, the first type of groove 1031 may be formed in the defining portion 102 by a dry etching process, but is not limited thereto.

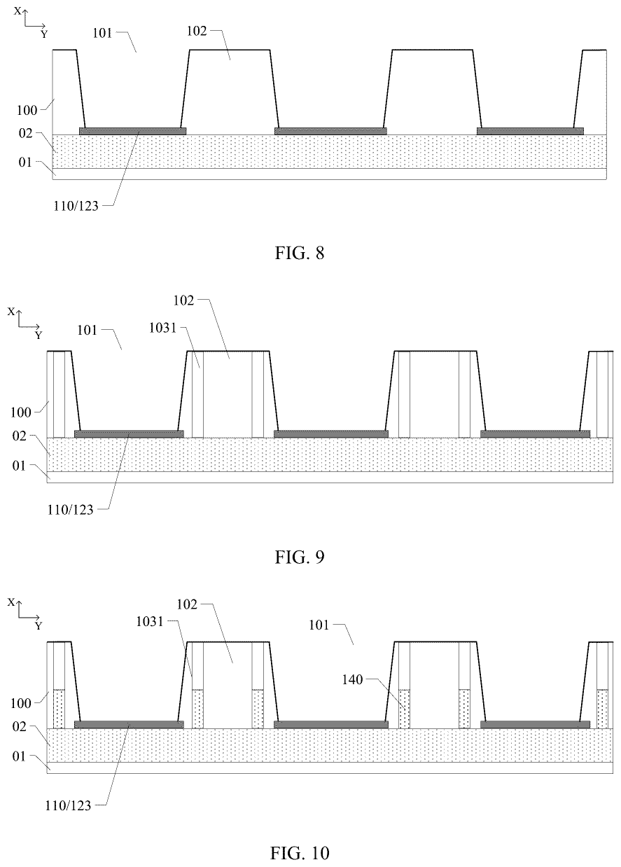

Next, as illustrated in FIG. 10, forming a first filling structure 140 in the first type of groove 1031, for example, the first filling structure 140 may be formed in the first type of groove 1031 by a method of inkjet printing, regarding a method of setting a size of the first filling structure 140 in the first direction X and a size of the first filling structure 140 in the second direction Y, reference may be made to the above-mentioned embodiments, which will not be repeated here.

As illustrated in FIG. 10, after forming the first filling structure 140, the manufacturing method further includes filling a part of the first type of groove 1031 except a space filled with the first filling structure 140 with a material of the defining portion 102. At this time, the first type of groove 1031 is filled with the first filling structure 140 and the material of the defining portion 102, and the first filling structure 140 in the first type of groove 1031 is closer to the display substrate 01 than the material of the defining portion 102. A part of the first type of groove where the first filling structure is located is the above-mentioned cavity 103 (as illustrated in FIG. 2).

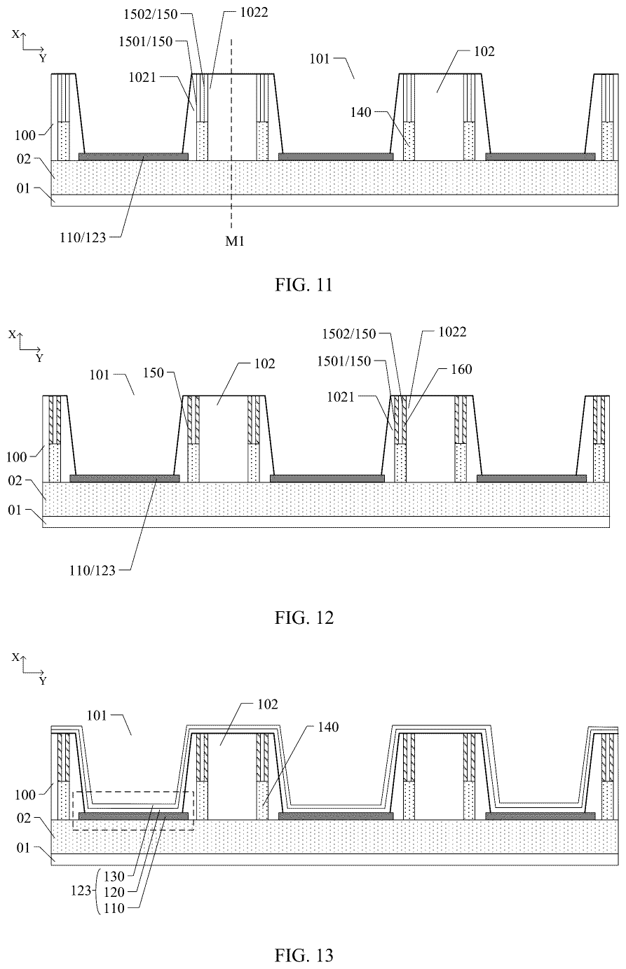

For example, as illustrated in FIG. 11, the manufacturing method of the display substrate further includes forming a plurality of second type of groove 150 in the defining portion 102 on a side of the first filling structure 140 away from the base substrate 01, and at least one second type of groove 150 surrounds the opening 101. For example, the second type of groove 150 may also be formed by the dry etching process, but is not limited thereto.

For example, as illustrated in FIG. 11, the plurality of second type of grooves 150 may include a first groove portion 1501 and a second groove portion 1502, and the defining portion 102 includes a first defining portion 1021 and a second defining portion 1022. For example, a position of the first defining portion 1021 and a position of the second defining portion 1022 can be determined according to a position of the light-emitting element 123, a position of the first groove portion 1501 and a position of the second groove portion 1502. For example, a center plane, perpendicular to the base substrate 01, of a portion of a surface of the defining portion 102 away from the base substrate 01 and parallel or approximately parallel to the base substrate 01 is M1, and an orthographic projection of the center plane M1 on the base substrate 01 is a centerline of an orthographic projection of the defining portion 102 on the base substrate 01. The first defining portion 1021 is farther away from the centerline of the orthographic projection of the defining portion 102 on the base substrate 01 than the second defining portion 1022.

Then, as illustrated in FIG. 12, the manufacturing method of the display substrate further includes forming a second filling structure 160 in the second type of groove 150, the material of the second filling structure 160 is different from the material of the defining portion 102, and the second filling structure 160 includes a light-transmitting material. For example, the first defining portion 1021, the second filling structure 160 in the first groove portion 1501, the second defining portion 1022, and the second filling structure 160 in the second groove portion 1502 are arranged in sequence to form a light filtering structure. For example, the second filling structure 160 may be formed in the second type of groove 150 by a method of chemical vapor deposition (CVD), regarding a method of setting a size of the second filling structure 160 in the first direction X and a size of the second filling structure 160 in the second direction Y, reference may be made to the above-mentioned embodiments, which will not be repeated here.

Finally, as illustrated in FIG. 13, forming a light-emitting functional layer 120 and a second electrode 130 of the light-emitting element 123 on a side of the defining portion 102 away from the base substrate 01, so that a surface of the first filling structure 140 away from the base substrate 01 is further away from the base substrate 01 than a surface of the part of the light-emitting functional layer 120 in the opening 101.

For example, as illustrated in FIG. 13, the light-emitting functional layer 120 of the light-emitting element 123 may include a plurality of film layers, for example, the plurality of film layers may include a hole injection layer (HIL), a hole transport layer (HTL), a light-emitting layer (EL), an electron transport layer (ETL), an electron injection layer (EIL) and other film layers. For example, the light-emitting functional layer 120 may further include a hole blocking layer (HBL), an electron blocking layer (EBL), a micro-cavity regulating layer, an exciton regulating layer or other functional film layers. For example, the hole injection layer (HIL) and the hole transport layer (HTL) are between the light-emitting layer (EL) and the first electrode 110, and the electron transport layer (ETL) and the electron blocking layer (EBL) are between the light-emitting layer (EL) and the second electrode 130. For example, the hole blocking layer (HBL) is between the light-emitting layer (EL) and the second electrode 130. For example, the electron blocking layer (EBL) is between the light-emitting layer (EL) and the first electrode 110. For example, the light-emitting functional layer 120 may further include a plurality of structures in a stacked manner to improve a light-emitting efficiency.

The following statements should be noted:
(1) The accompanying drawings related to the embodiment(s) of the present disclosure involve only the structure(s) in connection with the embodiment(s) of the present disclosure, and other structure(s) can be referred to common design(s).
(2) In case of no conflict, features in one embodiment or in different embodiments of the present disclosure can be combined.

The foregoing is merely exemplary embodiments of the disclosure, but is not used to limit the protection scope of the disclosure. The protection scope of the disclosure shall be defined by the attached claims.

1. A display substrate, comprising:
a base substrate;
a plurality of sub-pixels on the base substrate, wherein each of at least part of the plurality of sub-pixels comprises a light-emitting element, the light-emitting element comprises a light-emitting functional layer, a first electrode and a second electrode on both sides of the light-emitting functional layer in a first direction, the first electrode is between the light-emitting functional layer and the base substrate, and the first direction is perpendicular to the base substrate;
a pixel-defining pattern, the pixel-defining pattern comprising a plurality of openings and a defining portion that surrounds the plurality of openings, at least a portion of the light-emitting element being in the opening,
wherein the defining portion comprises at least one cavity, and the cavity surrounds at least one opening, and the display substrate further comprises a first filling structure, and the first filling structure is in the cavity, and a surface, away from the base substrate, of the first filling structure is farther away from the base substrate than a surface, away from the base substrate, of at least a portion of the light-emitting functional layer which is in contact with the first electrode in the opening.

2. The display substrate according to claim 1, wherein a minimum distance in a second direction between an edge of a surface of the defining portion at a side away from the base substrate and an edge of an orthographic projection of the first filling structure on the base substrate, which are adjacent to each other, is a first distance, and the second direction is a direction perpendicular to an extending direction of the edges; a distance between a center line of an orthographic projection of the defining portion on the display substrate and an orthographic projection of a first filling structure next to the center line on the display substrate is a second distance, the first distance is smaller than the second distance, and the center line is parallel to an extending direction of the defining portion.

3. The display substrate according to claim 2, wherein two cavities are arranged between two adjacent sub-pixels that are arranged in the second direction, and orthographic projections of the two cavities on the base substrate are on two side of the center line, respectively.

4. The display substrate according to claim 1, wherein the defining portion further comprises a plurality of grooves, at least one of the plurality of grooves surrounds the opening, and the groove is on a side of the cavity away from the substrate, the display substrate further comprises a second filling structure, the second filling structure is in the groove, a material of the second filling structure is different from a material of the defining portion, and the second filling structure comprises a light-transmitting material,
wherein the plurality of grooves comprise a first groove portion and a second groove portion, and the defining portion comprises a first defining portion and a second defining portion, and in a second direction, the first defining portion, the second filling structure in the first groove portion, the second defining portion, and the second filling structure in the second groove portion are arranged in sequence to form a light filtering structure, and the second direction is perpendicular to an extending direction of the defining portion, the first defining portion is farther away from a center line of an orthographic projection of the defining portion on the base substrate than the second defining portion, and the first groove portion is farther from the center line than the second groove portion.

5. The display substrate according to claim 4, wherein an orthographic projection of the first groove portion on the base substrate and an orthographic projection of the second groove portion on the base substrate overlap with an orthographic projection of a same cavity on the base substrate.

6. The display substrate according to claim 4, wherein a surface of the second filling structure away from the base substrate is flush with at least a portion of a surface of the defining portion away from the base substrate.

7. The display substrate according to claim 4, wherein a surface of the second filling structure close to the base substrate is flush with at least a portion of the surface of the first filling structure away from the base substrate.

8. The display substrate according to claim 4, wherein in the second direction, a size of the second filling structure is smaller than a size of the first filling structure.

9. The display substrate according to claim 4, wherein the first defining portion, the second filling structure in the first groove portion, the second defining portion, and the second filling structure in the second groove portion in the light filtering structure each satisfy:
$$d = λ / ( 4 * n )$$
wherein, d represents a thickness of any one of the first defining portion, the second filling structure in the first groove portion, the second defining portion, and the second filling structure in the second groove portion in the second direction, A represents a wavelength of incident light, n represents a refractive index of any one of the first defining portion, the second filling structure in the first groove portion, the second defining portion, and the second filling structure in the second groove portion.

10. The display substrate according to claim 9, wherein, in the light filtering structure, a thickness d1 of the first defining portion in the second direction is greater than a thickness d3 of the second filling structure in the first groove portion in the second direction.

11. The display substrate according to claim 9, wherein, in the light filtering structure, a refractive index n1 of the first defining portion and a refractive index n2 of the second defining portion respectively satisfy:
$$1.43 \leq n 1 \leq 1.47 , and 1.43 \leq n 2 \leq 1.47 .$$
in the light filtering structure, a thickness d1 of the first defining portion and a thickness d2 of the second defining portion respectively satisfy:
$$75 nm \leq d 1 \leq 130 nm , 75 nm \leq d 2 \leq 130 nm .$$

12. (canceled)

13. The display substrate according to claim 9, wherein, in the light filtering structure, a refractive index n3 of the second filling structure in the first groove portion and a refractive index n4 of the second filling structure in the second groove portion respectively satisfy:
$$1. 83 \leq n 3 \leq 1.87 , 1.83 \leq n 4 \leq 1.87 .$$
in the light filtering structure, a thickness d3 of the second filling structure in the first groove portion and a thickness d4 of the second filling structure in the second groove portion respectively satisfy:
$$60 nm \leq d 1 \leq 100 nm , 60 nm \leq d 2 \leq 100 nm .$$

14. (canceled)

15. The display substrate according to claim 2, wherein a size of the first filling structure in the first direction is not greater than ½ of a maximum size of the defining portion in the first direction,
in the second direction, a size of the first filling structure is 1/10 to ⅙ of a maximum size of the defining portion.

16. (canceled)

17. The display substrate according to claim 1, wherein a surface of the first filling structure close to the base substrate is flush with a bottom surface of the defining portion close to the base substrate.

18. The display substrate according to claim 17, wherein an orthographic projection of the first filling structure on the base substrate does not overlap with an orthographic projection of the first electrode on the base substrate.

19. The display substrate according to claim 1, wherein a material of the first filling structure is a light-shielding material,
a thermal conductivity K of the material of the first filling structure satisfies: 350<K<550.

20. (canceled)

21. The display substrate according to 20 claim 1, wherein a material of the first filling structure comprises silver.

22. The display substrate according to claim 10, wherein at least two light filtering structures are arranged between two adjacent sub-pixels arranged in the second direction,
the material of the second filling structure comprises silicon nitride.

23-24. (canceled)

25. A manufacturing method of a display substrate, comprising:
forming a first electrode, a light-emitting functional layer, and a second electrode of a light-emitting element on the base substrate;
before forming the light-emitting functional layer, forming a pixel-defining pattern on the first electrode, wherein the pixel-defining pattern comprises a plurality of openings and a defining portion that surrounds the plurality of openings, each of the plurality of openings exposes at least a portion of the first electrode;
forming a first type of groove in the defining portion, the first type of groove surrounding at least one of the plurality of openings; and
forming a first filling structure in the first type of groove, wherein a surface, away from the base substrate, of the first filling structure is farther away from the base substrate than a surface, away from the base substrate, of at least a portion of the light-emitting functional layer in the opening.

26. The manufacturing method of the display substrate according to claim 25, wherein, after forming the first filling structure, the manufacturing method further comprises:
filling a portion of the first type of groove other than a space filled with the first filling structure with a material of the defining portion;
forming a plurality of second type of grooves in the defining portion on a side of the first filling structure away from the base substrate, wherein at least one second type of groove surrounds the opening, the plurality of second type of grooves comprises a first groove portion and a second groove portion, and the defining portion comprises a first defining portion and a second defining portion;
forming second filling structures in the second type of grooves, wherein a material of the second filling structures is different from the material of the defining portion, and the second filling structures comprise a light-transmitting material; the first defining portion, the second filling structure in the first groove portion, the second defining portion, and the second filling structure in the second groove portion are arranged in sequence to form a light filtering structure.
